(19) United States
(12) Patent Application Publication
(10) Pub. No.: US 2024/0304761 A1
(43) Pub. Date: Sep. 12, 2024

(54) DISPLAY DEVICE AND METHOD OF MANUFACTURING THE SAME

(71) Applicant: Samsung Display Co., LTD., Yongin-si (KR)

(72) Inventor: Su Jin SUNG, Yongin-si (KR)

(73) Assignee: Samsung Display Co., LTD., Yongin-si (KR)

(21) Appl. No.: 18/480,061

(22) Filed: Oct. 3, 2023

(30) Foreign Application Priority Data
Mar. 8, 2023 (KR) 10-2023-0030767

(51) Int. Cl. H01L 33/44

(52) U.S. Cl. CPC H01L 33/44; H01L 2933/0025

(57) ABSTRACT

A method of manufacturing a display device includes positioning a display panel in an accommodating space of a stage, positioning a black matrix unit on an upper surface of a wall of the stage surrounding the accommodating space, and coating a window to cover the black matrix unit and the display panel. The black matrix unit and the window protrude beyond the display panel.

### CROSS REFERENCE TO RELATED APPLICATION(S)

This application claims priority to and benefits of Korean Patent Application No. 10-2023-0030767 under 35 U.S.C. § 119, filed on Mar. 8, 2023, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

As information technology develops, an importance of a display device, which is a connection medium between a user and information, has been highlighted. In response to this, a use of a display device such as a liquid crystal display device and an organic light emitting display device is increasing.

Display panels of various shapes are being produced according to various demands of a user. For example, the display panel may have a circular shape or may have a shape of which an edge is curved.

In order to protect the display panel and cover fixtures, attaching a window having an area larger than that of the display panel on the display panel is essential. The coating of the window has an advantage in that the method can correspond to the display panel of various shapes, but has a disadvantage in that the area of the coated window may not be wider than the area of the display panel. A method of laminating a pre-manufactured window with a display panel has a problem in that a defect may occur due to an air bubble, a foreign substance, and the like in a lamination process and an additional cost occurs to manufacture windows of various shapes.

### SUMMARY

An object to be solved is to provide a display device and a method of manufacturing the same capable of reducing a defect rate of a lamination process, corresponding to display panels of various shapes, and covering fixtures in addition to the display panel by configuring a window to be wider than the display panel.

According to an embodiment of the disclosure, a method of manufacturing a display device may include positioning a display panel in an accommodating space of a stage, positioning a black matrix unit on an upper surface of a wall of the stage surrounding the accommodating space, and coating a window to cover the black matrix unit and the display panel. The black matrix unit and the window may protrude beyond the display panel.

The method may further include cutting an edge of the black matrix unit and an edge of the window. After the cutting, the black matrix unit and the window may protrude beyond the display panel.

The method may further include performing a surface treatment on an inner surface of the wall with an anti-adhesion material. A height of the wall may be greater than a height of the display panel in a thickness direction of the display panel.

A portion of the black matrix unit may overlap the upper surface of the wall in a plan view, and another portion of the black matrix unit may overlap the display panel in a plan view.

The another portion of the black matrix unit may be spaced apart from the display panel in the thickness direction.

A portion of the window may be interposed between the another portion of the black matrix unit and the display panel.

The black matrix unit may include a substrate and a black matrix pattern printed on the substrate.

After the coating of the window, the window may contact an entire upper surface of the substrate, a portion of a lower surface of the black matrix pattern, and an entire upper surface of the display panel.

The method may further include performing a surface treatment on an upper surface of the wall with an anti-adhesion material. A height of the wall and a height of the display panel may be the same in a thickness direction of the display panel.

A portion of the black matrix unit may overlap the upper surface of the wall in a plan view, and another portion of the black matrix unit may overlap the display panel in a plan view.

The black matrix unit may include a carrier substrate and a black matrix pattern on the carrier substrate.

The method may further include transferring the black matrix pattern so that a portion of the black matrix pattern contacts an edge of the display panel, and removing the carrier substrate.

After the coating of the window, the window may contact an entire upper surface of the black matrix pattern and a portion of an upper surface of the display panel.

According to an embodiment of the disclosure, a display device may include a display panel, a black matrix unit of which a portion of a lower surface overlaps an edge of the display panel, and a window covering the black matrix unit and the display panel. The black matrix unit and the window may protrude beyond the display panel.

The black matrix unit may be spaced apart from the display panel in a thickness direction of the display panel.

A portion of the window may be interposed between the black matrix unit and the display panel.

The black matrix unit may include a substrate and a black matrix pattern printed on the substrate.

The window may contact an entire upper surface of the substrate, a portion of a lower surface of the black matrix pattern, and an entire upper surface of the display panel.

The black matrix unit may be a black matrix pattern, and a portion of a lower surface of the black matrix pattern may contact the display panel.

The window may contact an entire upper surface of the black matrix pattern and a portion of an upper surface of the display panel.

The display device and the method of manufacturing the same according to the disclosure may reduce a defect rate of a lamination process, respond to display panels of various shapes, and cover fixtures in addition to the display panel by configuring a window to be wider than the display panel.

### BRIEF DESCRIPTION OF THE DRAWINGS

The above and other features of the disclosure will become more apparent by describing in further detail embodiments thereof with reference to the accompanying drawings, in which:

FIG. 1 is a schematic diagram illustrating a display panel according to an embodiment of the disclosure;

FIG. 2 is a schematic diagram of an equivalent circuit of a sub-pixel according to an embodiment of the disclosure;

FIG. 3 is a schematic diagram illustrating a method of driving the sub-pixel of FIG. 2;

FIG. 4 is a schematic diagram illustrating a method of laminating a previously manufactured window with a display panel;

FIG. 5 is a schematic diagram illustrating a method of coating a window on the display panel;

FIGS. 6 to 10 are schematic diagrams illustrating a method of manufacturing a display device according to an embodiment of the disclosure; and

FIGS. 11 to 16 are schematic diagrams illustrating a method of manufacturing a display device according to another embodiment of the disclosure.

### DETAILED DESCRIPTION OF THE EMBODIMENTS

Hereinafter, various embodiments of the disclosure will be described in detail with reference to the accompanying drawings so that those skilled in the art may readily carry out the disclosure. The disclosure may be implemented in various different forms and is not limited to the embodiments described herein.

In order to clearly describe the disclosure, parts that are not related to the description are omitted, and the same or similar elements are denoted by the same reference numerals or symbols throughout the specification. Therefore, the above-described reference numerals may be used in other drawings.

In addition, sizes and thicknesses of each component shown in the drawings are arbitrarily shown for convenience of description, and thus the disclosure is not necessarily limited to those shown in the drawings. In the drawings, thicknesses may be exaggerated to clearly express various layers and areas.

In addition, an expression “is the same” in the description includes “is substantially the same”. For example, the expression “is the same” includes “the same enough” understood by those of ordinary skilled in the art. Other expressions may also be expressions in which “substantially” is omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

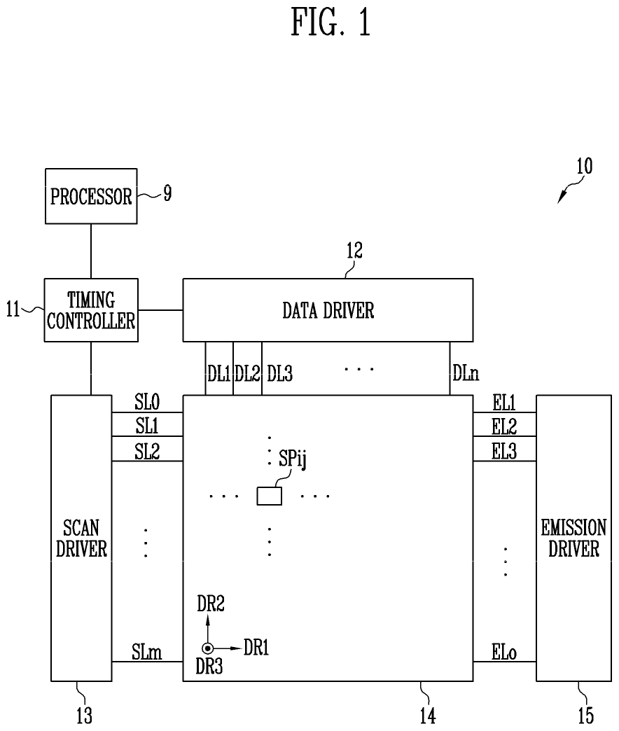

FIG. 1 is a schematic diagram illustrating a display panel according to an embodiment of the disclosure.

Referring to FIG. 1, the display panel 10 according to an embodiment of the disclosure may include a processor 9, a timing controller 11, a data driver 12, a scan driver 13, a pixel unit 14, and an emission driver 15.

The processor 9 may provide an image frame. The image frame may include a first color grayscale, a second color grayscale, and a third color grayscale with respect to each pixel. The first color grayscale may be a grayscale for expressing a first color, the second color grayscale may be a grayscale for expressing a second color, and the third color grayscale may be a grayscale for expressing a third color. The processor 9 may be an application processor, a central processing unit (CPU), a graphics processing unit (GPU), or the like.

The processor 9 may provide a control signal for the image frame. The control signal may include a horizontal synchronization signal (Hsync), a vertical synchronization signal (Vsync), and a data enable signal. The vertical synchronization signal may include multiple pulses, and may indicate that a previous frame period is ended and a current frame period is started based on a time point at which each of pulses is generated. An interval between adjacent pulses of the vertical synchronization signal may correspond to one frame period. The horizontal synchronization signal may include multiple pulses, and may indicate that a previous horizontal period is ended and a new horizontal period is started based on a time point at which each of pulses is generated. An interval between adjacent pulses of the horizontal synchronization signal may correspond to one horizontal period. The data enable signal may have an enable level with respect to specific horizontal periods and a disable level with respect to remaining periods. In case that the data enable signal is at the enable level, the data enable signal may indicate that color grayscales are supplied in corresponding horizontal periods.

The timing controller 11 may render the color grayscales to correspond to a structure of the pixel unit 14 and provide the rendered color grayscales to the data driver 12. The timing controller 11 may provide a clock signal, a scan start signal, and the like to the scan driver 13. The timing controller 11 may provide a clock signal, an emission stop signal, and the like to the emission driver 15.

The data driver 12 may generate data voltages to be provided to data lines DL1, DL2, DL3, . . . , and DLn using the color grayscales and the control signals received from the timing controller 11. For example, the data driver 12 may sample the color grayscales using the clock signal and apply the data voltages corresponding to the color grayscales to the data lines DL1 to DLn in a pixel row unit. n may be an integer greater than zero. A pixel row may correspond to sub-pixels connected to a same scan line and emission line.

The scan driver 13 may generate scan signals to be provided to scan lines SL0, SL1, SL2, . . . , and SLm using the clock signal, the scan start signal, and the like from the timing controller 11. For example, the scan driver 13 may sequentially provide scan signals having a turn-on level of pulse to the scan lines SL1 to SLm. For example, the scan driver 13 may be configured in a form of a shift register, and may generate the scan signals with a method of sequentially transferring a scan start signal in a form of a turn-on level of pulse to a next stage circuit under control of the clock signal. m may be an integer greater than zero.

The emission driver 15 may generate emission signals to be provided to emission lines EL1, EL2, EL3, . . . , and ELo using the clock signal, the emission stop signal, and the like from the timing controller 11. For example, the emission driver 15 may sequentially provide emission signals having a turn-off level of pulse to the emission lines EL1 to ELo. For example, the emission driver 15 may be configured in a form of a shift register, and may generate emission signals with a method of sequentially transferring an emission stop signal in a form of a turn-off level of pulse to a next stage circuit under control of the clock signal. o may be an integer greater than zero.

The pixel unit 14 includes sub-pixels. Each sub-pixel SPij may be connected to a corresponding data line, scan line, and emission line. Each of i and j may be an integer greater than 0. The sub-pixel SPij may be a sub-pixel in which a scan transistor is connected to an i-th scan line and a j-th data line.

The pixel unit 14 may include sub-pixels emitting light of a first color, sub-pixels emitting light of a second color, and sub-pixels emitting light of a third color. The first color, the second color, and the third color may be different colors. For example, the first color may be one of red, green, and blue, the second color may be another one of red, green, and blue, and the third color may be the other one of red, green, and blue. In an embodiment, magenta, cyan, and yellow may be used instead of red, green, and blue as the first to third colors. However, for convenience of description, embodiments will be described based on that the first color is red, the second color is green, and the third color is blue.

The pixel unit 14 may be disposed in various shapes such as Diamond Pixel™, RGB-Stripe, S-stripe, Real RGB, and normal PENTILE™.

Embodiments will be described based on that the sub-pixels of the pixel unit 14 are arranged in a first direction DR1 and a second direction DR2 perpendicular to the first direction DR1. In an embodiment, an emission direction of the sub-pixels may be a third direction DR3 perpendicular to the first direction DR1 and the second direction DR2.

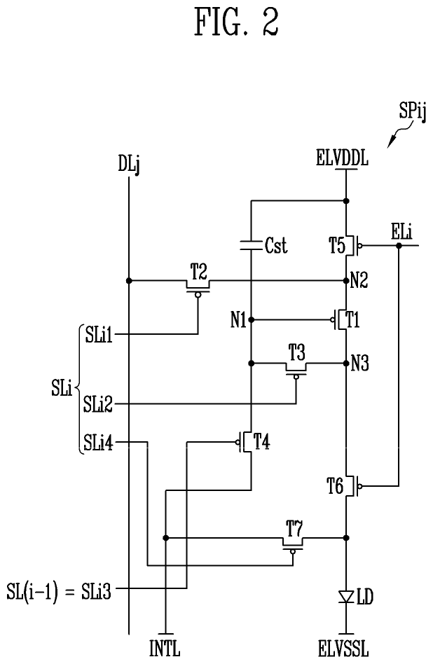

FIG. 2 is a schematic diagram of an equivalent circuit of a sub-pixel according to an embodiment of the disclosure.

Referring to FIG. 2, a sub-pixel SPij may include transistors T1, T2, T3, T4, T5, T6, and T7, a storage capacitor Cst, and a light emitting element LD.

Hereinafter, a circuit including P-type transistor is described as an embodiment. However, those skilled in the art will be able to design a circuit configured of an N-type transistor by differentiating a polarity of a voltage applied to a gate terminal. Similarly, those skilled in the art will be able to design a circuit configured of a combination of a P-type transistor and an N-type transistor. The P-type transistor may be a transistor in which a current amount increases in case that a voltage difference between a gate electrode and a source electrode increases in a negative direction. The N-type transistor may be a transistor in which a current amount increases in case that a voltage difference between a gate electrode and a source electrode increases in a positive direction. The transistor may be in a form such as a thin film transistor (TFT), a field effect transistor (FET), and a bipolar junction transistor (BJT).

The first transistor T1 may have a gate electrode connected to a first node N1, a first electrode connected to a second node N2, and a second electrode connected to a third node N3. The first transistor T1 may be a driving transistor.

The second transistor T2 may have a gate electrode connected to a scan line SLi1, a first electrode connected to a data line DLj, and a second electrode connected to the second node N2. The second transistor T2 may be a scan transistor.

The third transistor T3 may have a gate electrode connected to a scan line SLi2, a first electrode connected to the first node N1, and a second electrode connected to the third node N3. The third transistor T3 may be a diode connection transistor.

The fourth transistor T4 may have a gate electrode connected to a scan line SLi3, a first electrode connected to the first node N1, and a second electrode connected to an initialization line INTL. The fourth transistor T4 may be a gate initialization transistor.

The fifth transistor T5 may have a gate electrode connected to an i-th emission line Eli, a first electrode connected to a first power line ELVDDL, and a second electrode connected to the second node N2. The fifth transistor T5 may be an emission transistor.

The sixth transistor T6 may have a gate electrode connected to the i-th emission line ELi, a first electrode connected to the third node N3, and a second electrode connected to an anode of the light emitting element LD. The sixth transistor T6 may be an emission transistor. In another embodiment, the gate electrode of the sixth transistor T6 may be connected to another emission line different from the emission line connected to the gate electrode of the fifth transistor T5.

The seventh transistor T7 may have a gate electrode connected to a scan line SLi4, a first electrode connected to the initialization line INTL, and a second electrode connected to the anode of the light emitting element LD. The seventh transistor T7 may be a light emitting element initialization transistor.

A first electrode of the storage capacitor Cst may be connected to the first power line ELVDDL and a second electrode may be connected to the first node N1.

The anode of the light emitting element LD may be connected to the second electrode of the sixth transistor T6 and a cathode may be connected to a second power line ELVSSL. The light emitting element LD may be a light emitting diode. The light emitting element LD may be an organic light emitting element (organic light emitting diode), an inorganic light emitting element (inorganic light emitting diode), a quantum dot/well light emitting element (quantum dot/well light emitting diode), or the like. Although FIG. 2 illustrates one light emitting element LD in a pixel, the disclosure is not limited thereto, and multiple light emitting elements may be provided in each pixel in another embodiment. The light emitting elements may be connected in series, parallel, series-parallel, or the like. The light emitting element LD of each sub-pixel SPij may emit light in one of the first color, the second color, and the third color.

The first power line ELVDDL may be supplied with a first power voltage, the second power line ELVSSL may be supplied with a second power voltage, and the initialization line INTL may be supplied with an initialization voltage. For example, the first power voltage may be greater than the second power voltage. For example, the initialization voltage may be equal to or greater than the second power voltage. For example, the initialization voltage may correspond to a smallest data voltage of the color grayscales. In another embodiment, the initialization voltage may be less than the data voltages of the color grayscales.

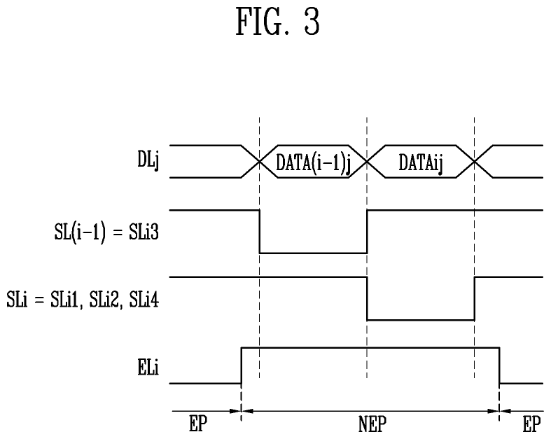

FIG. 3 is a schematic diagram illustrating a method of driving the sub-pixel of FIG. 2.

Hereinafter, for convenience of description, it is assumed that the scan lines SLi1, SLi2, and SLi4 are i-th scan lines SLi and the scan line SLi3 is an (i−1)-th scan line SL (i−1). However, a connection of the scan lines SLi1, SLi2, SLi3, and SLi4 may be various according to embodiments. For example, the scan line SLi4 may be the (i−1)-th scan line or an (i+1)-th scan line.

First, an emission signal of a turn-off level (logic high level) may be applied to the i-th emission line ELi, a data voltage DATA (i-1)j for an (i−1)-th sub-pixel may be applied to the data line DLj, and a scan signal of a turn-on level (logic low level) may be applied to the scan line SLi3. The high/low of the logic level may vary according to whether a transistor is a P-type or an N-type.

Since a scan signal of a turn-off level is applied to the scan lines SLi1 and SLi2, the second transistor T2 may be turned off, and the data voltage DATA (i−1)j may not be input to the i-th sub-pixel SPij.

Since the fourth transistor T4 is turned on, the first node N1 may be connected to the initialization line INTL, and thus a voltage of the first node N1 may be initialized. Since the emission signal of the turn-off level is applied to the emission line ELi, the transistors T5 and T6 may be turned off, and light emission of the light emitting element LD by an initialization voltage may be prevented.

Next, a data voltage DATAij for the i-th sub-pixel PXij may be applied to the data line DLj, and the scan signal of the turn-on level may be applied to the scan lines SLi1 and SLi2. Accordingly, the transistors T2, T1, and T3 may be turned on, and the data line DLj and the first node N1 may be electrically connected with each other. Therefore, a compensation voltage obtained by subtracting a threshold voltage of the first transistor T1 from the data voltage DATAij may be applied to the second electrode of the storage capacitor Cst (for example, the first node N1), and the storage capacitor Cst may maintain a voltage corresponding to a difference between the first power voltage and the compensation voltage. Such a period may be a threshold voltage compensation period or a data writing period.

In case that the scan line SLi4 is on the turn-on level, since the seventh transistor T7 is turned on, the anode of the light emitting element LD and the initialization line INTL may be connected with each other, and the light emitting element LD may be initialized to a charge amount corresponding to a voltage difference between the initialization voltage and the second power voltage.

Thereafter, as the emission signal of the turn-on level is applied to the i-th emission line ELi, the transistors T5 and T6 may be turned on. Therefore, a driving current path connecting the first power line ELVDDL, the fifth transistor T5, the first transistor T1, the sixth transistor T6, the light emitting element LD, and the second power line ELVSSL may be formed.

An amount of driving current flowing from the first electrode to the second electrode of the first transistor T1 may be adjusted by the voltage maintained in the storage capacitor Cst. The light emitting element LD may emit light with a luminance corresponding to the driving current. The light emitting element LD may emit light until the emission signal of the turn-off level is applied to the emission line ELi.

In case that the emission signal is in the turn-on level, sub-pixels receiving the corresponding emission signal may be in a display state. Therefore, a period in which the emission signal is in the turn-on level may be an emission period EP (or an emission allowable period). In case that the emission signal is in the turn-off level, sub-pixels may be in a non-display state. Therefore, a period in which the emission signal is in the turn-off level may be a non-emission period NEP (or an emission disallowable period).

The non-emission period NEP described with reference to FIG. 3 is for preventing the sub-pixel SPij from emitting light with an undesired luminance during the initialization period and the data writing period.

One or more non-emission periods NEP may be additionally provided while data written to the sub-pixel SPij is maintained (for example, one frame period). This may be for effectively expressing a low grayscale by reducing the emission period EP of the sub-pixel SPij, or for smoothly blurring a motion of an image.

FIG. 4 is a schematic diagram illustrating a method of laminating a previously manufactured window with the display panel.

Referring to FIG. 4, a display device DDa may include a display panel 10, an adhesive layer ADH, a black matrix BM, and a window WINa.

The window WINa may be previously manufactured to correspond to a shape of the display panel 10. The window WINa may be manufactured with a transparent material such as glass or plastic. The area of the window WINa may be larger than the area of the display panel 10. The area may correspond to a plane defined by the first direction DR1 and the second direction DR2 in which the sub-pixels of the display panel 10 are arranged.

The black matrix BM may be configured with a color film. For example, a color of the black matrix BM may be black. The black matrix BM may be positioned on a lower surface of an edge of the window WINa.

The window WINa may be attached to the display panel 10 by the adhesive layer ADH. An attaching process may be a laminating process. The black matrix BM may contact an outermost periphery of the display panel 10. The black matrix BM may be positioned so that a portion of the display panel 10 other than the pixel unit 14 is not visually recognized by a user.

According to an embodiment, the area of the window WINa may be sufficiently wide, and thus various fixtures attached to the display panel 10 may be covered. However, a method of laminating the previously manufactured window WINa with the display panel 10 may create a defect due to an air bubble, a foreign substance, and the like, and an additional cost may occur to manufacture the window WINa of various shapes.

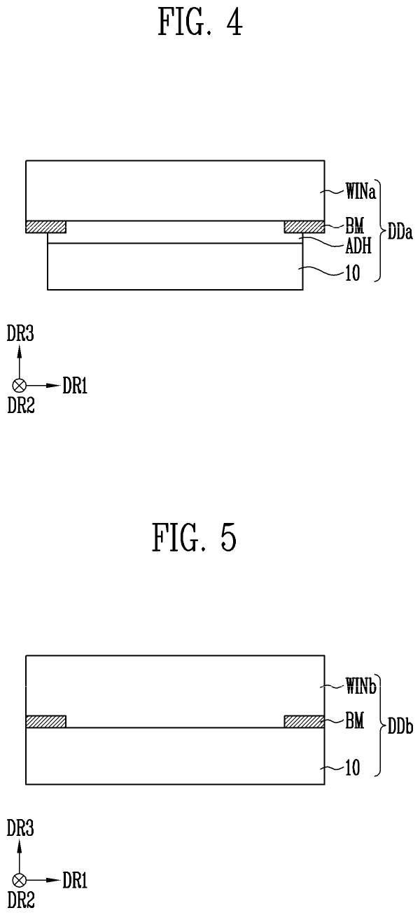

FIG. 5 is a schematic diagram illustrating a method of coating the window on the display panel.

Referring to FIG. 5, the display device DDb may include a display panel 10, the black matrix BM, and a window WINb.

The black matrix BM may be configured with a color film. For example, the color of the black matrix BM may be black. The black matrix BM may be positioned on an upper surface of an edge of the display panel 10.

The window WINb may be coated on the black matrix BM and the display panel 10. For example, the window WINb may be manufactured by applying a coating solution on the black matrix BM and the display panel 10 and curing the coating solution using ultraviolet rays or heat.

A method of coating the window WINb on the display panel 10 may have an advantage that the method may readily respond to the display panel 10 of various shapes. However, the method of coating the window WINb on the display panel may have a disadvantage that increasing the area of the coated window WINb to be wider than the area of the display panel 10 is difficult.

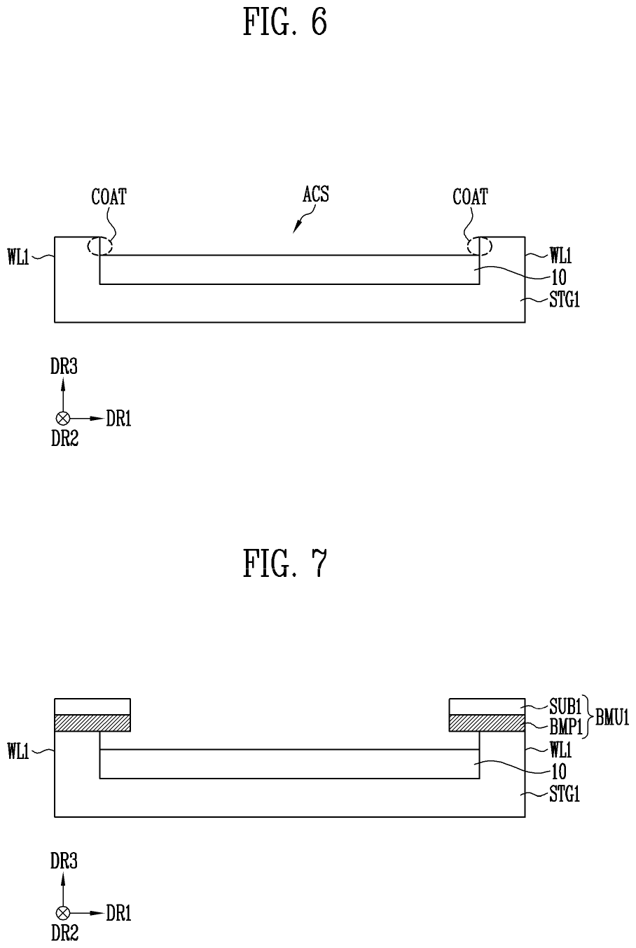

FIGS. 6 to 10 are schematic diagrams illustrating a method of manufacturing a display device according to an embodiment of the disclosure.

Referring to FIG. 6, a stage STG1 may be provided. The stage STG1 may include an accommodating space ACS and a wall WL1 surrounding the accommodating space ACS.

An inner surface of the wall WL1 of the stage STG1 may be surface-treated with an anti-adhesion material. Surface treatment may be performed by various methods such as coating and film attachment. For example, as an anti-adhesion material, a material such as TEFLON™ may be used. The anti-adhesion material may prevent adhesion between the window and the stage STG1 during subsequent window coating.

A display panel 10 may be positioned in the accommodating space ACS of the stage STG1. A height of the wall WL1 may be greater than a height of the display panel 10. For example, even after the display panel 10 is positioned, a portion of the inner surface of the wall WL1 may be exposed to an outside. The height may be a length in the third direction DR3.

Referring to FIG. 7, a black matrix unit BMU1 may be positioned on the wall WL1. The black matrix unit BMU1 may have a structure in which a black matrix pattern BMP1 is printed on a substrate SUB1. For example, the black matrix pattern BMP1 may include a black organic material, chromium oxide (CrOₓ), or the like in which a black pigment is mixed.

The black matrix unit BMU1 may be positioned so that the black matrix pattern BMP1 faces an upper surface of the wall WL1 and an upper surface of the display panel 10. A portion of the black matrix unit BMU1 may overlap the upper surface of the wall WL1, and another portion of the black matrix unit BMU1 may overlap the display panel 10 in a plan view. As described above, since the height of the wall WL1 is higher than the height of the display panel 10, the another portion of the black matrix unit BMU1 may be spaced apart from the display panel 10 in a height direction (third direction DR3).

In an embodiment, the black matrix pattern BMP1 may be printed on the substrate SUB1, and the substrate SUB1 may not be removed. The substrate SUB1 may provide a supporting force so that the black matrix pattern BMP1 is not inclined before window coating.

Referring to FIG. 8, the window WIN1 may be coated to cover the black matrix unit BMU1 and the display panel 10. For example, the window WIN1 may be coated by applying a coating solution on the display panel 10 and the black matrix unit BMU1 and curing the coating solution using ultraviolet rays or heat.

The coating solution for forming the window WIN1 may include a base resin. The base resin is not particularly limited, and may include, for example, a thermosetting resin material. For example, the base resin may be a polyurethane-based resin, a urethane-acrylate-based resin, a polyurea-based resin, an epoxy-based resin, a silicone-based resin, or the like. The coating solution for forming the window WIN1 may include two or more types of base resins with a same type of resin and different side chain structures. In case that the two or more types of base resins include a same type of resin, mixing may be readily facilitated. However, the disclosure is not limited thereto.

The coating may be formed by a method. For example, the window WIN1 may be formed by roll coating, silk screen coating, spray coating, slit coating, or the like.

A portion of the window WIN1 may be interposed between the another portion of the black matrix unit BMU1 and the display panel 10. Therefore, a portion of the window WIN1 may serve as an adhesive between the black matrix unit BMU1 and the display panel 10. The window WIN1 may be coated to contact the entire upper surface of the substrate SUB1, a portion of a lower surface of the black matrix pattern BMP1, and the entire upper surface of the display panel 10.

The black matrix unit BMU1 and the window WIN1 may protrude beyond the display panel 10. For example, the black matrix unit BMU1 and the window WIN1 may protrude beyond the display panel 10 in the first direction DR1 and the second direction DR2.

Therefore, according to the embodiment, even though the coating type window WIN1 is used, since the window WIN1 having the area larger than the area of the display panel 10 is formed, various fixtures attached to the display panel 10 may be covered. As various fixtures are covered by the black matrix unit BMU1, the various fixtures may not be visually recognized by the user. The coating type window WIN1 may have an advantage in that the coating type window WIN1 may readily respond to the display panels 10 of various shapes at a low cost.

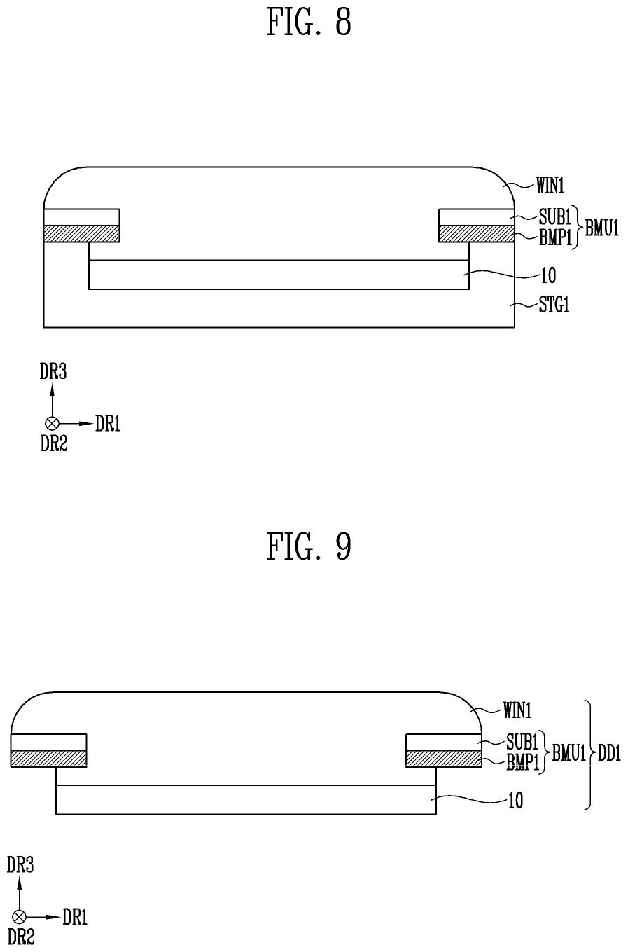

Referring to FIG. 9, after coating of the window WIN1 is completed, the display device DD1 may be separated from the stage STG1. As described above, since the inner surface of the wall WL1 of the stage STG1 is surface-treated with an anti-adhesion material, adhesion between the stage STG1 and the window WIN1 may be prevented, and the display device DD1 and the stage STG1 may be readily separated.

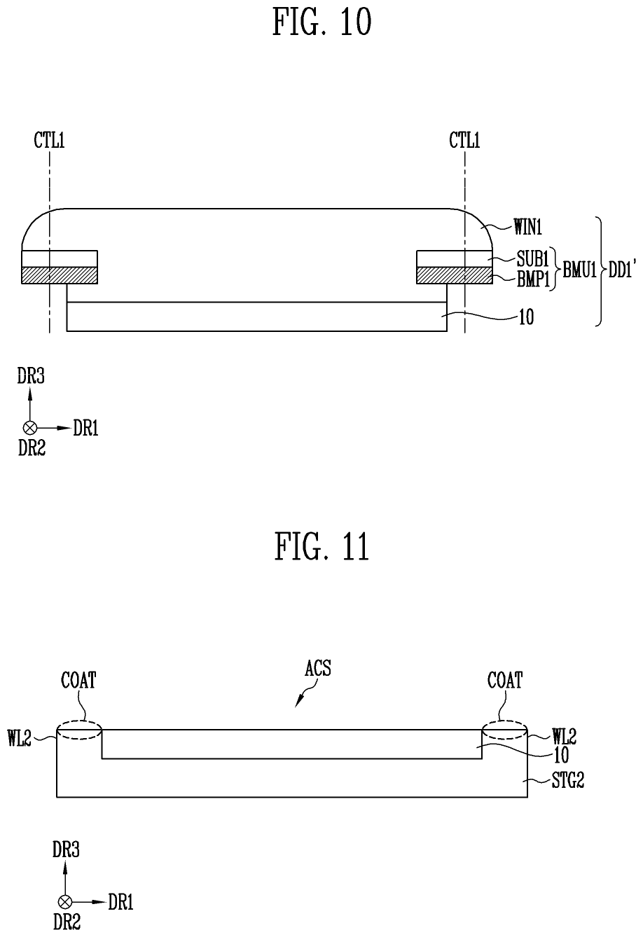

Referring to FIG. 10, an edge of the black matrix unit BMU1 and an edge of the window WIN1 may be cut to form a display device DD1′ of a desired shape. The black matrix unit BMU1 and the window WIN may be cut by a method such as a laser process and a computer numerical control (CNC) process. A cutting line CTL1 shown in FIG. 10 is not limited thereto, and for example, the edge of the window WIN1 may be cut so that a corner has a curved shape.

The cut black matrix unit BMU1 and the cut window WIN1 may protrude beyond the display panel 10. For example, even though the cutting process is performed as necessary, the area of the window WIN1 may be larger than the area of the display panel 10. However, the disclosure is not limited thereto, and the cutting process of FIG. 10 may not be required for the display device DD1 of FIG. 9.

FIGS. 11 to 16 are schematic diagrams illustrating a method of manufacturing a display device according to another embodiment of the disclosure.

Referring to FIG. 11, a stage STG2 may be provided. The stage STG2 may include an accommodating space ACS and a wall WL2 surrounding the accommodating space ACS.

An upper surface of the wall WL2 of the stage STG2 may be surface-treated with an anti-adhesion material. Surface treatment may be performed by various methods such as coating and film attachment. For example, as an anti-adhesion material, a material such as TEFLON™ may be used. The anti-adhesion material may prevent a black matrix pattern BMP2 from fixed to an upper portion of the wall WL2 in a subsequent process.

The display panel 10 may be positioned in the accommodating space ACS of the stage STG2. A height of the wall WL2 and a height of the display panel 10 may be the same. For example, after the display panel 10 is positioned, an inner surface of the wall WL2 may not be exposed to the outside. The height may be the length in the third direction DR3.

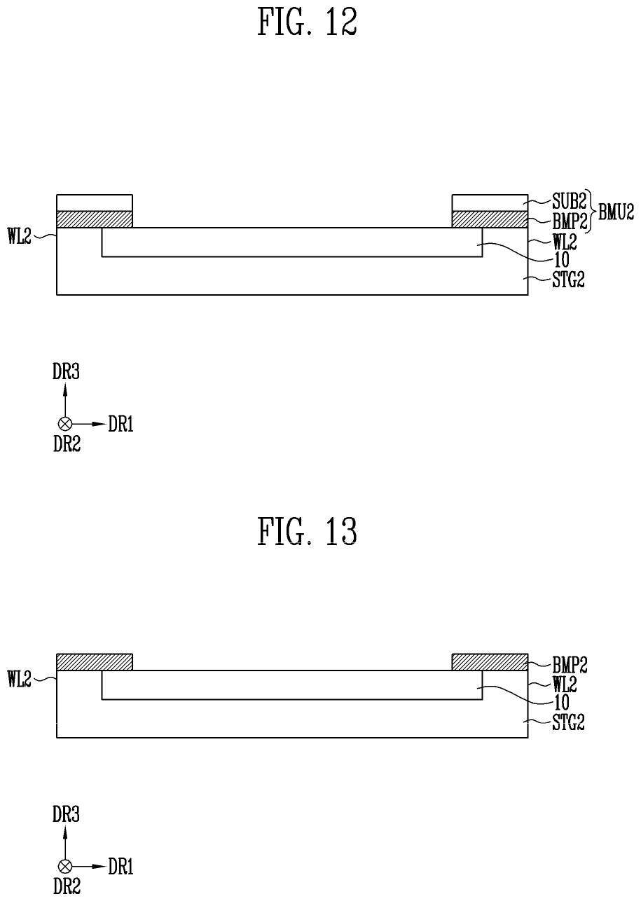

Referring to FIG. 12, a black matrix unit BMU2 may be positioned on the upper surface of the wall WL2. A portion of the black matrix unit BMU2 may overlap the upper surface of the wall WL2, and another portion of the black matrix unit BMU2 may overlap the display panel 10 in a plan view.

The black matrix unit BMU2 may include a carrier substrate SUB2 and the black matrix pattern BMP2 on the carrier substrate SUB2. The black matrix pattern BMP2 may include a black organic material or chromium oxide (CrOₓ) in which black pigment is mixed. As described above, since the height of the wall WL2 and the height of the display panel 10 are the same, the another portion of the black matrix unit BMU2 may contact the display panel 10 in the height direction (in the third direction DR3).

Referring to FIG. 13, a portion of the black matrix pattern BMP2 may be transferred to contact the outermost portion of the display panel 10. After a transfer process, the carrier substrate SUB2 may be removed. In an embodiment, the black matrix unit BMU2 and the black matrix pattern BMP2 may have a same configuration.

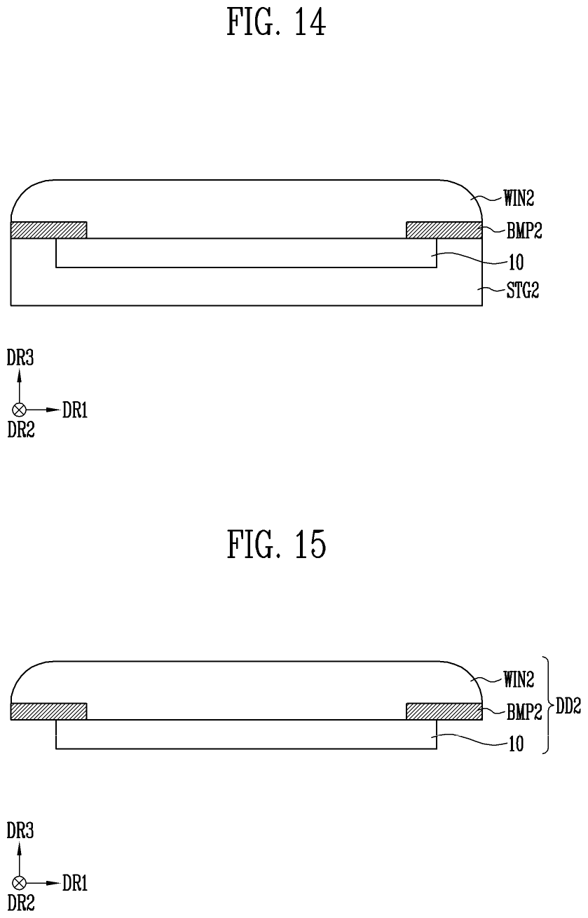

Referring to FIG. 14, the window WIN2 may be coated to cover the black matrix pattern BMP2 and the display panel 10. For example, the window WIN2 may be coated by applying a coating solution on the display panel 10 and the black matrix pattern BMP2 and curing the coating solution using ultraviolet rays or heat.

The coating solution for forming the window WIN2 may include a base resin. The base resin is not particularly limited, and may include, for example, a thermosetting resin material. For example, the base resin may be a polyurethane-based resin, a urethane-acrylate-based resin, a polyurea-based resin, an epoxy-based resin, a silicone-based resin, or the like.

The coating solution for forming the window WIN1 may include two or more types of base resins may include resins with a same type of resin and different side chain structures. In case that the two or more types of base resins include a same type of resin, mixing may be readily facilitated. However, the disclosure is not limited thereto.

The coating may be formed by a method. For example, the window WIN2 may be formed by roll coating, silk screen coating, spray coating, slit coating, or the like. The window WIN2 may be coated to contact the entire upper surface of the black matrix pattern BMP2 and a portion of an upper surface of the display panel 10.

The black matrix unit BMU2 and the window WIN2 may protrude beyond the display panel 10. For example, the black matrix pattern BMP2 and the window WIN2 may protrude beyond the display panel 10 in the first direction DR1 and the second direction DR2.

Therefore, according to the embodiment, even though the coating type window WIN2 is used, since the window WIN2 of the area larger than the area of the display panel 10 is formed, various fixtures attached to the display panel 10 may be covered. As various fixtures are covered by the black matrix pattern BMP2, the various fixtures may not be visually recognized by the user. The coating type window WIN2 may have an advantage in that the coating type window WIN2 may readily respond to the display panels 10 of various shapes at a low cost.

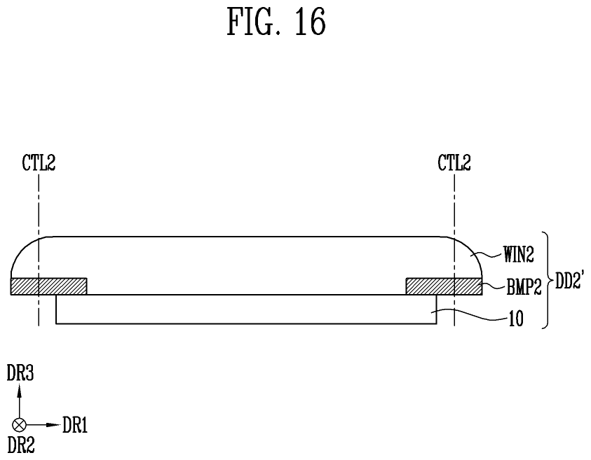

Referring to FIG. 15, after coating of the window WIN2 is completed, the display device DD2 may be separated from the stage STG2. As described above, since the upper portion of the wall WL2 of the stage STG2 is surface-treated with an anti-adhesion material, adhesion between the stage STG2 and the black matrix pattern BMP2 may be prevented, and the display device DD2 and the stage STG2 may be readily separated.

Referring to FIG. 16, an edge of the black matrix pattern BMP2 and an edge of the window WIN2 may be cut to form a display device DD12 of a desired shape. The black matrix unit BMU1 and the window WIN may be cut by a method such as a laser process and a computer numerical control (CNC) process. A cutting line CTL2 shown in FIG. 16 is not limited thereto, and for example, the edge of the window WIN2 may be cut so that a corner has a curved shape.

The cut black matrix pattern BMP2 and the cut window WIN2 may protrude beyond the display panel 10. For example, even though the cutting process is performed as necessary, the area of the window WIN2 may be larger than the area of the display panel 10. However, the disclosure is not limited thereto, and the cutting process of FIG. 16 may not be required for the display device DD2 of FIG. 15.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
positioning a display panel in an accommodating space of a stage;
positioning a black matrix unit on an upper surface of a wall of the stage surrounding the accommodating space; and
coating a window to cover the black matrix unit and the display panel,
wherein the black matrix unit and the window protrude beyond the display panel.

2. The method according to claim 1, further comprising:
cutting an edge of the black matrix unit and an edge of the window,
wherein after the cutting, the black matrix unit and the window protrude beyond the display panel.

3. The method according to claim 1, further comprising:
performing a surface treatment on an inner surface of the wall with an anti-adhesion material,
wherein a height of the wall is greater than a height of the display panel in a thickness direction of the display panel.

4. The method according to claim 3, wherein
a portion of the black matrix unit overlaps the upper surface of the wall in a plan view, and
another portion of the black matrix unit overlaps the display panel in a plan view.

5. The method according to claim 4, wherein the another portion of the black matrix unit is spaced apart from the display panel in the thickness direction.

6. The method according to claim 5, wherein a portion of the window is interposed between the another portion of the black matrix unit and the display panel.

7. The method according to claim 5, wherein the black matrix unit includes a substrate and a black matrix pattern printed on the substrate.

8. The method according to claim 7, wherein after the coating of the window, the window contacts an entire upper surface of the substrate, a portion of a lower surface of the black matrix pattern, and an entire upper surface of the display panel.

9. The method according to claim 1, further comprising:
performing a surface treatment on an upper surface of the wall with an anti-adhesion material,
wherein a height of the wall and a height of the display panel are the same in a thickness direction of the display panel.

10. The method according to claim 9, wherein
a portion of the black matrix unit overlaps the upper surface of the wall in a plan view, and
another portion of the black matrix unit overlaps the display panel in a plan view.

11. The method according to claim 10, wherein the black matrix unit includes a carrier substrate and a black matrix pattern on the carrier substrate.

12. The method according to claim 11, further comprising:
transferring the black matrix pattern so that a portion of the black matrix pattern contacts an edge of the display panel; and
removing the carrier substrate.

13. The method according to claim 12, wherein after the coating of the window, the window contacts an entire upper surface of the black matrix pattern and a portion of an upper surface of the display panel.

14. A display device comprising:
a display panel;
a black matrix unit of which a portion of a lower surface overlaps an edge of the display panel in a plan view; and
a window covering the black matrix unit and the display panel,
wherein the black matrix unit and the window protrude beyond the display panel.

15. The display device according to claim 14, wherein the black matrix unit is spaced apart from the display panel in a thickness direction of the display panel.

16. The display device according to claim 15, wherein a portion of the window is interposed between the black matrix unit and the display panel.

17. The display device according to claim 16, wherein the black matrix unit includes a substrate and a black matrix pattern printed on the substrate.

18. The display device according to claim 17, wherein the window contacts an entire upper surface of the substrate, a portion of a lower surface of the black matrix pattern, and an entire upper surface of the display panel.

19. The display device according to claim 14, wherein
the black matrix unit is a black matrix pattern, and
a portion of a lower surface of the black matrix pattern contacts the display panel.

20. The display device according to claim 19, wherein the window contacts an entire upper surface of the black matrix pattern and a portion of an upper surface of the display panel.
